(19) United States
(12) Patent Application Publication
(10) Pub. No.: US 2011/0037464 A1
(43) Pub. Date: Feb. 17, 2011

(54) TUNABLE GRAPHENE MAGNETIC FIELD SENSOR

(76) Inventors: Bruce Alvin Gurney, San Jose, CA (US); Ernesto E. Marinoro, Saratoga, CA (US); Simone Pisana, San Jose, CA (US)

Correspondence Address: ZILKA-KOTAB, PC- HIT, P.O. BOX 721120, SAN JOSE, CA, 95172-1120, US

(21) Appl. No.: 12/539,437

(22) Filed: Aug. 11, 2009

(51) Int. Cl. G01R 33/02

(52) U.S. Cl. 324/252

(57) ABSTRACT

A magnetic field sensor employing a graphene sense layer, wherein the Lorentz force acting on charge carriers traveling through the sense layer causes a change in path of charge carriers traveling through the graphene layer. This change in path can be detected indicating the presence of a magnetic field. The sensor includes one or more gate electrodes that are separated from the graphene layer by a non-magnetic, electrically insulating material. The application of a gate voltage to the gate electrode alters the electrical resistance of the graphene layer and can be used to control the sensitivity and speed of the sensor.

### FIELD OF THE INVENTION

The present invention relates generally magnetic field sensors and more particularly to a tunable Lorentz magnetoresistive magnetic field sensor employing a graphene sense layer.

### BACKGROUND OF THE INVENTION

Magnetoresistive sensors have been used in a variety of applications, including use in data recording systems such as magnetic disk drive systems. Traditionally sensors such as giant magnetoresistive sensors (GMR), anisotropic magnetoresistive sensors (AMR), and tunnel junction sensors (TMR) have been used to detect magnetic fields in applications such as magnetic disk drives. However, such sensors have inherent limitations that prevent their use at extremely small sizes, such as for reading nanoscale high density bits in a magnetic disk drive system.

Current technologies based on AMR, GMR or TMR magnetoresistive sensors are subject to thermal fluctuations of the magnetization direction in the ferromagnetic sense layers and spin-torque instabilities that increase as the sensor size is decreased, resulting in degraded signal to noise ratio. Furthermore, as the size of the magnetic bit to be measured is reduced, the sensor thickness and proximity to the magnet need to decrease in order to retain high sensitivity.

### SUMMARY OF THE INVENTION

The present invention provides a tunable magnetic field sensor that employs a layer of graphene as a magnetic field sensor layer. A plurality of electrodes are connected with the layer of graphene in such a manner that a sense current can be injected into the graphene layer and a change in voltage can be detected in response to an external magnetic field excitation. A gate electrode is separated from the graphene layer by a non-magnetic, electrically insulating material.

The sensor is a Lorentz magnetoresistive sensor wherein the presence of a magnetic field alters the path of charge carriers traveling through the layer of graphene via the Lorentz force. The application of a gate voltage at the gate electrode changes the resistance of the graphene layer, allowing the speed and sensitivity of the sensor to be tuned, even after the sensor has been manufactured. This advantageously allows the sensor to fit within design parameters even if manufacturing deviations and variations would have otherwise caused the sensor to fall outside of desired design specifications.

The sensor can include one gate electrode, which can be above the graphene layer (i.e. between the graphene layer and the sensor surface) or can be below the graphene layer (such that the graphene layer is between the gate electrode and the sensor surface). The sensor can also include a pair of gate electrodes such that the graphene layer is between the gate electrodes.

The presence of the gate electrodes not only provides an advantageous tuning mechanism, but also provides electrostatic shielding for the graphene layer. This shielding can be especially beneficial in preventing external electric fields from affecting the response of the sensor.

These and other features and advantages of the invention will be apparent upon reading of the following detailed description of preferred embodiments taken in conjunction with the Figures in which like reference numerals indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a magnetic data recording device in which a magnetic field sensor according to the present invention might be used;

FIG. 2 shows how the magnetic field decreases into the body of a magnetoresistive device when the sense layer is located 0 to 30 nm below the sensor surface and the magnetic field at several different different senses layers.

FIG. 3 is a side cross-sectional view showing a magnetic field sensor according to an embodiment of the invention;

FIG. 4 is a top down view showing a magnetic field sensor according to another embodiment of the invention;

FIG. 5 is a top down view showing a magnetic field sensor according to yet another embodiment of the invention; and

FIG. 6 shows the response of a sensor according to the invention to a magnetic field when the device is gated so that transport is dominated by electrons, holes or in a regime near the Dirac point where both are present.

### DETAILED DESCRIPTION OF THE PREFERRED EMBODIMENTS

The following description is of the best embodiments presently contemplated for carrying out this invention. This description is made for the purpose of illustrating the general principles of this invention and is not meant to limit the inventive concepts claimed herein.

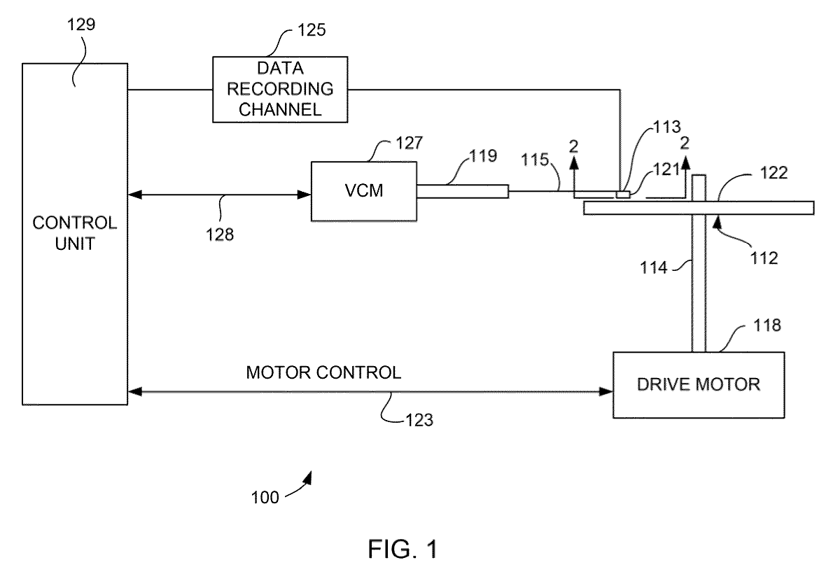

Referring now to FIG. 1, there is shown a disk drive 100 embodying this invention. As shown in FIG. 1, at least one rotatable magnetic disk 112 is supported on a spindle 114 and rotated by a disk drive motor 118. The magnetic recording on each disk is in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, slider 113 moves radially in and out over the disk surface 122 so that the magnetic head assembly 121 may access different tracks of the magnetic disk where desired data are written. Each slider 113 is attached to an actuator arm 119 by way of a suspension 115. The suspension 115 provides a slight spring force which biases slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of the magnetic disk 112 generates an air bearing between the slider 113 and the disk surface 122, which exerts an upward force or lift on the slider. The air bearing thus counter-balances the slight spring force of suspension 115 and supports the slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads 121 by way of recording channel 125.

The above described magnetic data recording system provides an illustration of an environment in which a magnetic field sensor according to the present invention might be employed. It should be clear, however, that this is by way of example only, and that a magnetic field sensor according to the present could be used in any of a variety of other applications and environments as well.

According to the present invention, a single or multiple sheets of graphene are used as the conducting channel in a Lorentz force based magnetic sensor. The use of graphene provides a distinct advantage over other previously proposed Lorentz magnetic field sensors, such as those that employ a semiconductor-based quantum well structure. In these prior-art quantum well structures, it is required that the magnetically active layer (the quantum well) be located a significant distance from the surface of the device in order to generate the necessary transport properties for the device to operate properly. Typically, devices according to the prior art are based on a two dimensional electron gas (2 DEG) formed in semiconductor heterostructures employing epitaxial growth, through molecular beam epitaxy. In order to generate the required high degree of epitaxy it is necessary to form a thick buffer layer beneath the 2 DEG of insulating materials. This precludes the insertion of a gate beneath the 2 DEG, making control of the device more difficult and requiring that a gate be placed above the device. In contrast, a metallic or other conducting layer can easily be located below a graphene sense layer, as will be described below.

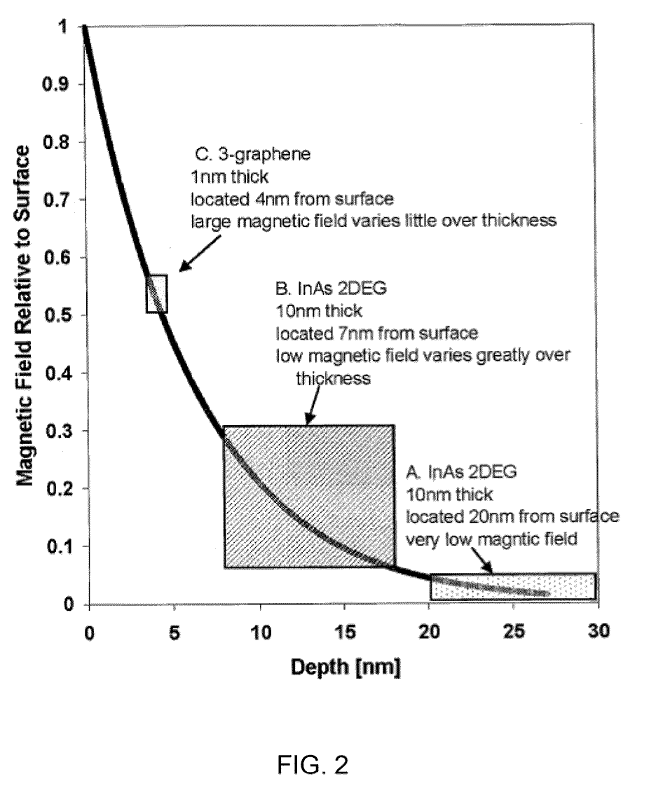

For magnetic scanning and magnetic recording applications the sense layer must be located sufficiently close to the surface so that the lateral resolution of the sensor is not degraded. For magnetic features to be resolved that are separated by a lateral distance d, the sense layer cannot be more than about d/2 in order to adequately resolve the location of the features. Thus, for future magnetic recording applications greater than 1 Tb/in², with a lateral separation of bits of about 20 nm, it is necessary for the sense layer to be no more that 10 nm away from the surface. As can be seen in FIG. 2 a typical 2 DEG structure requires approximately >15 nm of barrier and cap layers, and is therefore unsuitable for resolving magnetic features closer than about 30 nm.

An additional constraint on the detection of localized magnetic fields is the reduction of magnetic field above the surface of the magnetic media, which is called spacing loss. The magnetic field from bits written on a magnetic recording media decay approximately exponentially with a characteristic length of h=d/π, where d is the separation of adjacent bits. Thus to maintain even 36% of the field at the surface of the media, the sensor can be located no more that din from the surface, or about 7 nm from the surface if d=20 nm.

Furthermore, because the decay of magnetic field of din is so rapid, the magnetic field will drop significantly within the typical 2 DEG itself, because the channel is 10-12 nm thick. This further reduces the sensitivity of the device because the average magnetic field is much smaller than the magnetic field at the surface of the 2 DEG.

FIG. 2 illustrates by way of a particular example the disadvantages of using the prior-art devices and the advantages of using graphene instead. The curve shows how the magnetic field produced by an array of bits spaced by 20 nm decays from the surface of the sensor. The field strength decays rapidly, such that the field at a depth of 10 nm is only about 20% of the field at the surface of the sensor. Also displayed are three rectangles showing the depth where three different sense layers could be located and the magnetic field and range of magnetic field within the sense layer thickness for each sense layer. In the case of 2 DEG structures, cap layers, barriers and liners must be included in determining the depth. Additionally, in this example a top gate of 2 nm is also included for each sensor, as described below. For an InAs 2 DEG sense layer located 20 nm from the surface, a typical 2 DEG depth [Nguyen, C. et al, APL, 60, 1854, 1992], the magnetic field at the top of the sense layer has decreased to only about 3% of the field at the surface of the sensor, and drops to about 1% at the bottom of the sense layer (See sense layer A in FIG. 2). This clearly would yield poor performance compared to a sensor whose sense layer is closer to the surface. By moving the top of the 2 DEG to 8 nm from the surface, the situation is improved so that the magnetic field at the top of the sense layer is about 30% of that at the surface, but because the 2 DEG layer is thick, the field at the bottom is less than 5%, so on average the field remains a modest 22% of the surface value (See sense layer B in FIG. 2). What is needed is a sense layer that is thin and can be located at or near the device surface. The third sense layer, graphene, shown as layer C in FIG. 2, satisfies these requirements. In this specific example the thickness of 1 nm, corresponding to three layers of graphene, comprises the sense layer. We assume also that the sense layer is beneath a 2 nm top gate and 2 nm insulator, so that it's top surface is 4 nm from the surface. The magnetic field strength at its top is 56% of the surface and it varies less than 8% over its thickness. Over a single graphene sheet, with thickness of only about 0.3 nm the field will vary a negligible amount. Furthermore, it is possible to locate the sense layer closer to the surface, and in some cases at the surface. Overall, the use of graphene provides considerable improvements in many of the areas required for measurement of magnetic fields varying on the nanoscale.

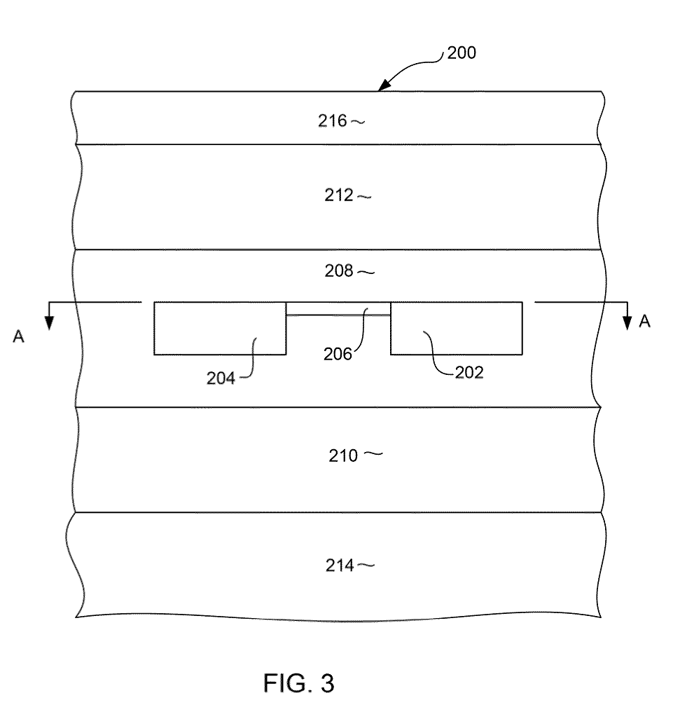

FIG. 3 illustrates a cross sectional view 200 according to a possible embodiment of the invention. The sensor 200 includes first and second electrodes 202, 204, and one or more sheets of graphene 206 forming a n-graphene layer and spanning between the electrodes 202, 204. By n-graphene layer we mean a layer containing n sheets of single layer graphene. The electrodes 202, 204 and n-graphene layer 206 can be embedded 20. within an insulation layer 208, preferably a high-k dielectric in order to screen the effect of charged impurities that are deleterious to transport. These include but are not limited to HfO₂, Al₂O₃, Si₃N₄, Y₂O₃, Pr₂O₃, Gd₂O₃, La₂O₃, TiO₂, ZrO₂, AlN, BN, SiC, Ta₂O₅, SrTiO₃, BaxSr1-xTiO₃, PbxZr1-xTiO₃. The sensor 200 can also include one or both of a bottom gate electrode 210 and a top gate electrode 212, the function of which will be described in greater detail below. The sensor 200 can be formed on a substrate 214, which can be, for example, a slider body of a slider 113 described above with reference to FIG. 1, or could be some other substrate in some other application. In addition, a protective overcoat 216 such as alumina or carbon can be provided over the top of the sensor 200 in order to protect the layers of the sensor 200 from damage and corrosion. The upper surface of the protective layer 216 is the upper surface of the magnetic field sensor, and in the case of a sensor used in a magnetic data recording system, is the surface that faces the magnetic medium 112 (FIG. 1). The first and second electrodes, as well as the top and bottom gate electrodes can be constructed of a non-magnetic, electrically conductive material, such as but not limited to Cu or Au or Pd as well as multi-layered and alloy metal contacts employed in the micro-electronics industry.

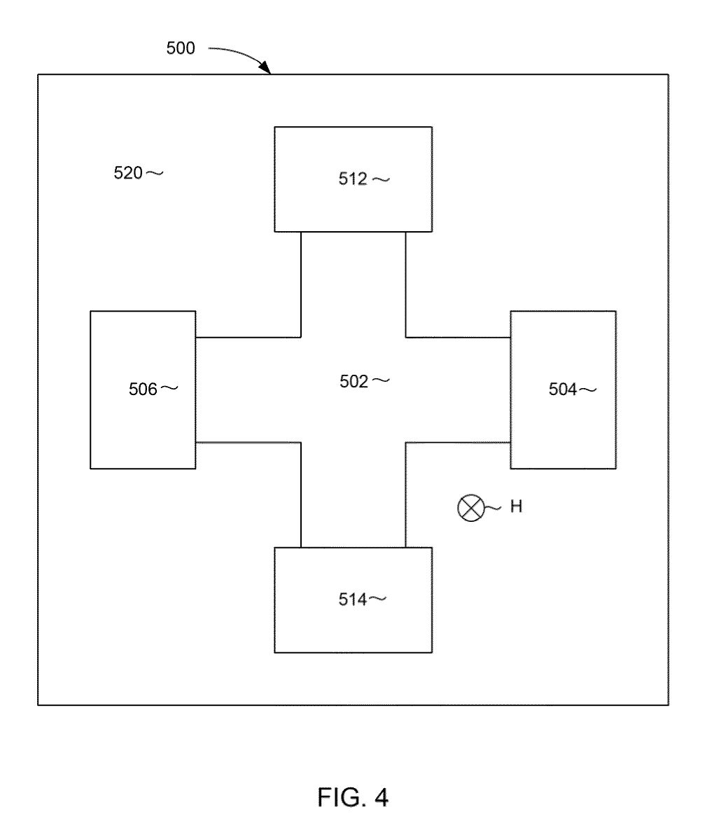

As mentioned above, the layer 206 is constructed of n-graphene. Graphene is a single atomic sheet of graphitic carbon atoms that are arranged into a honeycomb lattice. It can be viewed as a giant two-dimensional Fullerene molecule, an unrolled single wall carbon nanotube, or simply a single layer of lamellar graphite crystal. Charge carrier mobility values as high as 200,000 cm²/Vs at room temperature are achievable (Morozov et al, PRL 10, 016602, 2008). Graphene also possesses the advantageous property that its electrical resistance (or mobility of charge carriers) can be controlled by the application of a gate voltage, such as a voltage from one or both of the gate electrodes 210, 212. This feature will be discussed in greater detail below after further discussing the general operation of various possible embodiments of magnetic field sensors as described with reference to FIGS. 4-6.

With reference now to FIG. 4, the invention can also be embodied in a magnetic field sensor 500 formed as a Hall cross structure. Therefore, this sensor 500 includes a centrally located n-graphene layer 502, which acts as the magnetically active layer. The n-graphene layer 502 can be formed as a cross as shown, but could also be other shapes such as round, elliptical, etc. depending on the shape of the magnetic bit or field to be read. The structure also includes first and second current lead electrodes 504, 506, which are connected with and extend from opposed edges of the n-graphene layer. Therefore, the current lead electrodes 504, 506 are opposite one another across the n-graphene layer 502. The sensor 500 also includes first and second voltage lead electrodes 512, 514, which are connected with and extend from the n-graphene layer 502 in between leads 504 and 506 and are at locations opposite one another. The layers 502, 504, 506, 514, 512 can be embedded in a non-magnetic, electrically insulating material 520 such as a high-k dielectric in order to screen the effect of charged impurities that are deleterious to transport. These include but are not limited to HfO₂, Al₂O₃, Si₃N₄, Y₂O₃, Pr₂O₃, Gd₂O₃, La₂O₃, TiO₂, ZrO₂, AlN, BN, SiC, Ta₂O₅, SrTiO₃, BaxSr1-xTiO₃, PbxZr1-xTiO₃.

The current lead electrodes 504, 506 can be used to inject charge carriers through the n-graphene layer 502. As discussed above, these charge carriers can be electrons or holes. In the absence of a magnetic field, the charge carriers will travel predominantly straight through the n-graphene layer 502 from one current lead electrode 504 to the other current lead electrode 506. However, in the presence of a magnetic field H oriented perpendicular to the plane of the layers 502, 504, 506, 512, 514, the charge carriers will be deflect by the Lorentz force as described above. The charge carriers are deflected generally toward one of the voltage lead electrodes 512 and away from the opposite voltage lead electrode 514. While not all of the charge carriers will be deflected into the one voltage lead electrode 512, the presence of the magnetic field causes a net larger amount of the charge carriers to enter one of the voltage lead electrodes 512 than the other 514. This results in a net difference between the relative voltage potentials of the voltage lead electrodes 512, 514. This net voltage difference can be detected to determine the presence of the magnetic field H.

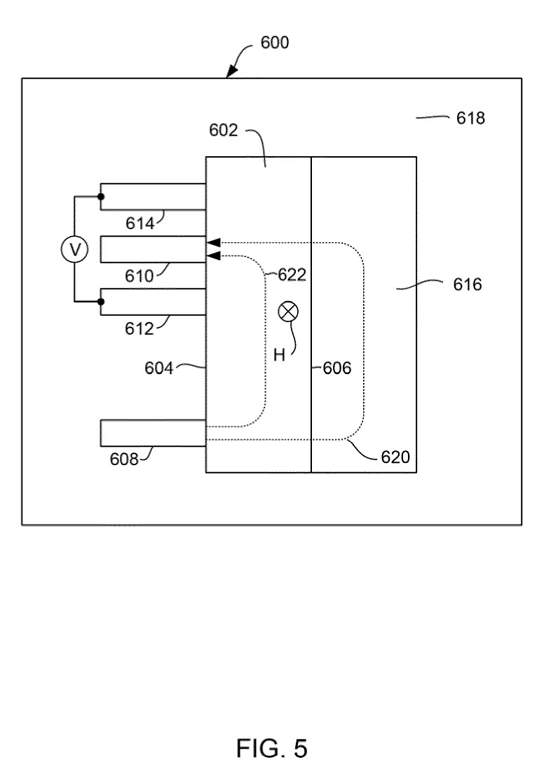

With reference now to FIG. 5, yet another embodiment of a magnetic field sensor 600 is described called an Extraordinary magneto resistance sensor (see T. D. Boone et al, IEEE Electron Device Let. 30, 117 (2009)). The sensor 600 includes a n-graphene layer 602 having first and second opposed edges 604, 606. First and second electrically conductive current leads 608, 610 are connected with the first side 604 of the n-graphene layer 602. In addition, first and second voltage leads 612, 614 are also connected with the first side of the n-graphene layer 602. The first and second current leads 608, 610 and first and second voltage leads 612, 614 can be constructed of an electrically conductive material such as Au or Cu or Pd as well as multi-layered and alloy metal contacts employed in the micro-electronics industry. In the embodiment shown in FIG. 5, the leads 608, 612, 610 and 614 are arranged in an IVIV arrangement with voltage leads being located at either side of one of the current leads. However, other arrangements and numbers of leads are possible as well and the present invention need not be limited to the number and arrangement of leads shown.

An electrically conductive shunt structure 616 contacts the second edge 606 of the n-graphene layer 602. The shunt structure can be constructed of a non-magnetic, electrically conductive material such as Cu or Au or Pd as well as multi-layered and alloy metal contacts employed in the micro-electronics industry, and has a thickness into the plane of the page that can be much larger than the thickness of the n-graphene layer if desired 602 (which as mentioned above is only one or a few atoms thick). Therefore, the shunt 616 has a much lower electrical resistance than the graphene layer 602. The layers 602, 616 and leads 608, 610, 612, 614 can be embedded in a non-magnetic, electrically insulating layer 618 such a high-k dielectric in order to screen the effect of charged impurities that are deleterious to transport. These include but are not limited to HfO₂, Al₂O₃, Si₃N₄, Y₂O₃, Pr₂O₃, Gd₂O₃, La₂O₃, TiO₂, ZrO₂, AlN, BN, SiC, Ta₂O₅, SrTiO₃, BaxSr1-xTiO₃, PbxZr1-xTiO₃.

During operation, an electrical current is injected into the graphene layer 602 by the current leads 608, 610. In the absence of a magnetic field, a majority of the charge carriers (electrons or holes) pass through the n-graphene layer 602 to the lower resistance shunt layer 616, following a path indicated by dashed line 620. However, in the presence of a magnetic field H, oriented perpendicular to the plane of the layers 602, 616 more of the charge carriers are deflected into the n-graphene layer 602 and away from the shunt as a result of the Lorentz force. Some of the charge carriers, then, follow paths that are represented by line 622.

Because of the increased resistance of the n-graphene layer 602 compared with the shunt structure 616, the change in the path of the charge carriers results in a higher electrical resistance across the voltage leads 612, 614 when the charge carriers follow path 622 as compared with the resistance when the charge carriers follow the path 620. This change in electrical resistance can be measured across the voltage leads 612, 614 in order to determine the presence of an external field excitation within the region determined by leads 614 and 612. Said spacing determines the resolution of the magnetic sensor device as described in U.S. Pat. No. 7,295,406.

Various structures have been described above with reference to FIGS. 4-6 for constructing a magnetic field resistor using a n-graphene layer as a magnetically active layer of the sensor. With reference once again to FIG. 3, a novel control feature is described for optimizing the performance of a sensor using a graphene layer as a magnetically active layer in structures such as those described with reference to FIGS. 4-6. With reference then to FIG. 3, it can be seen that the sensor 200 has a lower or bottom gate electrode 210 and an upper or top gate electrode 212, each of which can be constructed of a non-magnetic, electrically conductive material such as Cu or Au or Pd as well as multi-layered and alloy metal contacts employed in the micro-electronics industry as discussed above. It should be pointed out that, the sensor 200 can be constructed with both of the gate electrodes 210, 212, but could also be constructed with only a bottom electrode 210 or only a top gate electrode 212.

The choice of whether to include only a bottom gate electrode 210, only a top gate electrode 212, or both gate electrodes is a matter of design choice that includes a balancing of performance factors. For example, the presence of the top gate electrode 212, increases the spacing between the graphene layer and the source of the magnetic field to be detected (such as the magnetic media in a data recording system). On the other hand, the presence of the top gate electrode 212 can act as a shield to prevent stray electric fields (such as from the surface of a magnetic media) from affecting the n-graphene layer 206.

The use of one or more of the gate electrodes 210, 212 can be used to tune the sensitivity and resistance of the magnetic field sensor 200. In extremely small nanoscale sensors such as the magnetic field sensor embodiments described above, manufacturing variations and deviations lead to variations in the performance and resistance of the manufactured sensors. This tuning feature of the sensor ensures that all manufactured sensors can maintain desired design sensitivity and resistance values even in spite of these manufacturing variations.

Graphene has the advantageous property that its resistance or charge carrier mobility can be controllably altered by the application of a gate voltage. The gate voltage is applied by an electrode that is not connected with the graphene layer, but is adjacent to and separated from the graphene layer by a dielectric material such as the layer 208 of FIG. 3. The application of a voltage to one or both of the gating electrodes 210, 212 allows for the control of the charge carrier areal density in the n-graphene layer 206, thereby affecting the device resistance, which determines the speed of the sensing circuitry. The use of the gating electrodes 210, 212 also allows control of the device sensitivity, which may not be reproducible from device to device at submicron sizes.

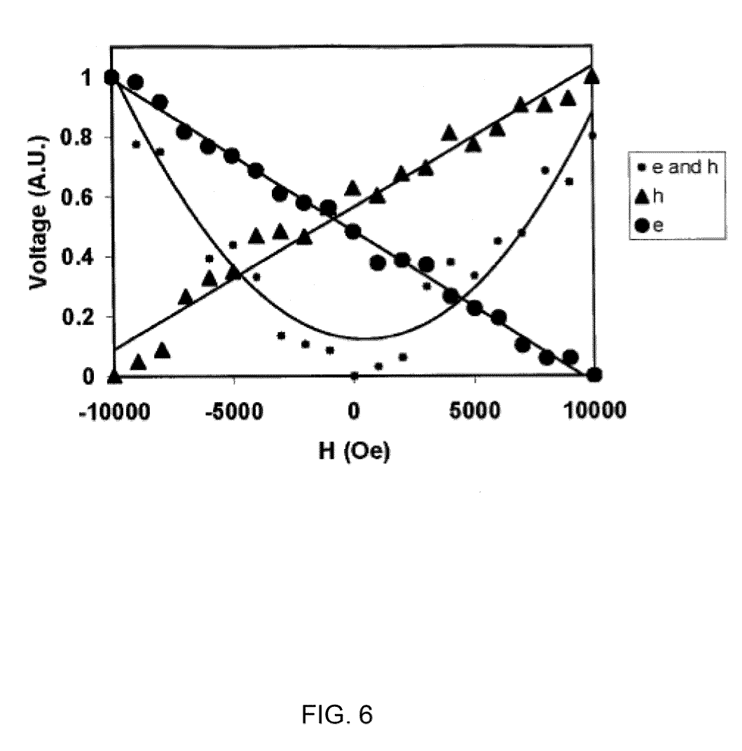

Graphene has another advantageous property related to the control of carriers by a gate voltage that is unique. In a voltage range around the Dirac point both electrons and holes can be simultaneously present, leading to novel operation of a Lorentz magnetoresistor. The Dirac point is the location in the band structure of graphene where the band cones meet at a point. Shown in FIG. 6 is the response of an EMR device to magnetic field under the influence of different applied gate voltages, corresponding to conduction predominantly through electron carriers, hole carriers, and a regime where both are present. When electrons dominate conduction in this device the response to the external magnetic field is linear. When conduction is predominantly through holes the response to a magnetic field is linear with a slope that is opposite to the one obtained with electron conduction. Thus, one method to confirm the response to a magnetic field is to measure that field with holes and again with electrons and compare the difference.

Importantly, near the Dirac point both holes and electrons can exist simultaneously. In this regime the response to magnetic field is quadratic to magnetic field. This quadratic response can be used for sensors requiring non-linear response or only requiring an absolute value of field. In addition, it can be used as a frequency doubler. An alternating magnetic field at frequency f will generate a signal at frequency 2 f from the device which is advantageous in signal detection and processing.

In addition to Hall sensors and EMR sensors other Lorentz magnetoresistors can be made with n-graphene, such as so called geometric magnetoresistors [J. Heremans, J. Phys. D. Appl. Phys. 26, 1149 (1993)]. In these devices the Hall effect is minimized by making the width where current flows much smaller than the length of the device, thereby minimizing the induced electric field. In a magnetic field, carriers flow at the Hall angle with respect to the electric field, thus traveling a longer distance through the sensor, increasing its resistance. The advantages that graphene provides, including use of a thin sense layer located close to the surface will improve geometric magnetoresistor devices.

Therefore, the present invention provides several advantages over prior art structures. Firstly, the sensing layer (n-graphene layer 206) can be made extremely thin (as small as a single carbon atom) while having excellent charge carrier mobility. Secondly, the sensing layer can be located extremely close to the surface. Thirdly, the resistance and speed of the sensor can be tuned by the use of a gating electrode (e.g. 212 or 210). Fourth, the gating electrodes 210, 214 can provide electromagnetic shielding for the sensing layer (n-graphene layer 206). Fifth, the implementation of a bottom gate is a straightforward part of fabrication and does not need to be part of the sensor growth. Sixth, the sense layer using graphene can be gated so that both electron and hole carriers are present, changing the response from linear in magnetic field to quadratic in magnetic field.

While various embodiments have been described above, it should be understood that they have been presented by way of example only, and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A tunable magnetic field sensor, comprising:
a layer of n-graphene;
a plurality of electrodes connected with the layer of n-graphene to supply a current through the layer of n-graphene and to measure a voltage change in response to the presence of a magnetic field; and
a gate electrode separated from the n-graphene layer by a non-magnetic, electrically insulating material.

2. The tunable magnetic field sensor as in claim 1 wherein the sensor has a surface and wherein the gate electrode is located between the layer of n-graphene and the surface.

3. The tunable magnetic field sensor as in claim 1 wherein the sensor has a surface and wherein gate electrode is located such that the n-graphene layer is located between the gate electrode and the surface.

4. The tunable magnetic field sensor as in claim 1 wherein the gate electrode is a first gate electrode, and wherein the sensor further comprises a second gate electrode, the first and second gate electrodes being located at opposite sides of the layer of n-graphene such that the layer of n-graphene is located between the first and second gate electrodes.

5. The tunable magnetic field sensor of claim 1 wherein the n-graphene layer consists of a single layer of graphene.

6. The tunable magnetic field sensor as in claim 1 wherein the n-graphene layer comprises a plurality of layers of graphene.

7. The tunable magnetic field sensor as in claim 1 wherein the n-graphene layer comprises 1 to 5 layers of graphene.

8. The tunable magnetic field sensor as in claim 1 wherein the voltage change is a result of the Lorentz force on charge carriers in the layer of n-graphene.

9. The tunable magnetic field sensor as in claim 1 wherein the layer of n-graphene is disposed between layers of electrically insulating, non-magnetic material.

10. The tunable magnetic field sensor as in claim 1 wherein the layer of n-graphene has a first edge and a second edge opposite the first edge, the sensor further comprising a first contact electrode connected with the first edge of the layer of graphene and a second contact electrode connected with the second edge of the layer of graphene.

11. The tunable magnetic field sensor as in claim 10 wherein the first and second contact electrodes inject a current into the layer of graphene and also measure a change in voltage across the layer of graphene.

12. The tunable magnetic field sensor as in claim 1 wherein the layer of graphene layer has dimensions configured to detect a magnetic bit to be sensed.

13. The tunable magnetic field sensor as in claim 1 further comprising:
first and second current electrodes located opposite one another across the layer of n-graphene and each connected with the layer of n-graphene; and
first and second voltage leads located opposite one another across the layer of graphene and each connected with the layer of graphene at a location between the first and second current leads.

14. The tunable magnetic field sensor as in claim 1 wherein the layer of n-graphene has a first edge and a second edge opposite the first edge, and further comprising:
a plurality of electrodes connected with first edge of the layer of n-graphene; and
an electrically conductive shunt electrically connected with a second edge of the n-graphene layer.

15. The tunable magnetic field sensor as in claim 1 wherein the layer of n-graphene has a first edge and a second edge opposite the first edge, and further comprising:
first and second current leads connected with the first edge of the layer of n-graphene;
first and second voltage leads connected with the first edge of the layer of n-graphene; and
an electrically conductive shunt electrically connected with a second edge of the n-graphene layer.

16. The tunable magnetic field sensor as in claim 15 wherein the one of the first and second current electrodes is located between the first and second voltage leads.

17. A tunable magnetic field sensor as in claim 1 wherein the tunable magnetic field sensor has a surface and wherein the n-graphene layer is located less than 20 nm from the surface of the sensor.

18. A tunable magnetic field sensor as in claim 1 wherein the current comprises hole carriers.

19. A tunable magnetic field sensor as in claim 1 wherein the current comprises both hole and electron carriers simultaneously present.

20. A tunable magnetic field sensor as in claim 19 where a 2 f component of the sensor response is used to measure a magnetic field amplitude and frequency.
